(19) United States
(12) Patent Application Publication
(10) Pub. No.: US 2015/0132938 A1
(43) Pub. Date: May 14, 2015

(54) Methods and Systems for Forming Reliable Gate Stack on Semiconductors

(71) Applicant: Intermolecular, Inc., San Jose, CA (US)

(72) Inventors: Khaled Ahmed, Anaheim, CA (US); Frank Greer, Pasadena, CA (US)

(73) Assignee: Intermolecular, Inc., San Jose, CA (US)

(21) Appl. No.: 14/079,410

(22) Filed: Nov. 13, 2013

(51) Int. Cl. H01L 29/51; H01L 21/28

(52) U.S. Cl. CPC H01L 29/517; H01L 21/28176
USPC 438/591

(57) ABSTRACT

Methods are provided for the deposition of high-k gate dielectric materials which are doped with fluorine and/or nitrogen to improve the performance and reliability. The high-k dielectric materials may include at least one of hafnium oxide, hafnium silicon oxide, hafnium aluminum oxide, zirconium oxide, zirconium silicon oxide, zirconium aluminum oxide, titanium oxide, titanium silicon oxide, or titanium aluminum oxide. The fluorine dopant is provided from a layer including titanium nitride or amorphous silicon, where the layer is doped with at least one of fluorine or nitrogen. The dopants diffuse into the high-k dielectric material during a subsequent anneal process.

### TECHNICAL FIELD

Provided are methods of forming semiconductor devices, and more particularly, to methods, and devices forming from the methods, for forming gate dielectric layers.

### BACKGROUND OF THE INVENTION

As integrated circuit feature sizes decrease, other device dimensions also decrease to maintain the proper device operation. For example, as gate conductor widths decrease, the thickness of the gate dielectric needs to decrease to provide proper capacitance to control the transistor.

To meet the requirements of sub-30 nm devices, an equivalent oxide thickness (EOT) of less than 1.0 nm is needed. Using SiO₂ as the gate dielectric, it is difficult to maintain its dielectric property below about 2 nm thickness due to the high tunneling leakage.

High-k materials, (i.e., dielectric materials having higher dielectric constant k than that of SiO₂ (k˜3.9)), can provide high capacitance with greater thickness, and thus have been studied as replacement materials for SiO₂. For example, a film with a high-k value of 20, (which can be obtained with various transition metal oxides such as hafnium oxide), can be about five times thicker than a SiO₂ film and have a similar capacitance value. The thicker gate dielectric layer of high-k material can reduce tunneling leakage current through the gate, enabling sub-30 nm metal oxide semiconductor field effect transistor (MOSFET) devices.

The fabrication of high-k gate dielectric layers can provide difficulty in realizing the full benefits of the high dielectric constant. For example, processing high-k dielectric layers in the presence of oxygen at elevated temperatures, (e.g., high-k deposition or subsequent anneal processes), can form a SiO₂ interfacial layer between the silicon substrate and the high-k layer. The SiO₂ interfacial layer can increase the effective oxide thickness, reducing the capacitance of the gate dielectric layer. Further, high-k gate dielectrics can contain a greater number of bulk traps and interface traps than thermally grown SiO₂ gate dielectrics. The traps can degrade the device performance, due to issues such as threshold voltage instability (positive bias temperature instability (PBTI) and negative bias temperature instability (NBTI)), and Frenkel-Poole tunneling leakage.

Thus there is a need to develop improved methods and structures involving high-k gate dielectrics and related semiconductor devices.

### SUMMARY OF THE DESCRIPTION

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, high-k gate dielectric materials are doped with fluorine or nitrogen to improve the performance and reliability. The high-k dielectric materials may be at least one of hafnium oxide, zirconium oxide, or titanium oxide. The fluorine dopant is provided from a layer comprising titanium nitride doped with at least one of fluorine or nitrogen. The dopants diffuse into the high-k dielectric material during a subsequent anneal process.

In some embodiments, high-k gate dielectric materials are doped with fluorine or nitrogen to improve the performance and reliability. The high-k dielectric materials may be at least one of hafnium oxide, zirconium oxide, or titanium oxide. The fluorine dopant is provided from a layer comprising silicon doped with at least one of fluorine or nitrogen. The dopants diffuse into the high-k dielectric material during a subsequent anneal process.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates an exemplary metal-oxide semiconductor field effect transistor (MOSFET) device according to some embodiments.

FIGS. 2A-2B illustrate a fabrication sequence for an exemplary metal gate electrode according to some embodiments.

FIG. 3 illustrates a flow chart of an ALD deposition of high-k metal oxide dielectric materials according to some embodiments.

FIG. 4 illustrates a flow chart of an ALD deposition of high-k metal oxide dielectric materials according to some embodiments.

FIG. 5 illustrates a processing system enabling deposition according to some embodiments.

### DETAILED DESCRIPTION OF THE DISCLOSURE

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

The term “substrate” as used herein may refer to any workpiece on which formation or treatment of material layers is desired. Substrates may include, without limitation, silicon, germanium, silicon-germanium alloys, gallium arsenide, indium gallium arsenide, indium gallium antimonide, silica, sapphire, zinc oxide, silicon carbide, aluminum nitride, Spinel, coated silicon, silicon on oxide, silicon carbide on oxide, glass, gallium nitride, indium nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter.

The terms “high-k material”, “high-k layer”, “high-k dielectric”, “high-k dielectric material”, and “high-k dielectric layer”, as used herein, will be considered to be equivalent and will refer to a material and/or layer that has a dielectric constant of greater than 5.

The term “dangling bond” will be understood to an unsatisfied valence on an immobilized atom associated with a material or layer (typically at or near the surface or an interface). Those skilled in the art will understand that this is a term of art and is not generally accepted to represent a physical configuration of the atom.

The term “doping/passivating species” is used herein to refer to atomic or molecular species that are able to diffuse through the dielectric material and bind to dangling bonds at the interface between the semiconductor channel material and the gate dielectric material.

Current MOS transistors, both planar and three-dimensional (such as FinFETs) use high-k dielectrics as the gate oxide layer together with a very thin interlayer (IL), typically SiO₂. These high-k dielectrics are used in conjunction with layers of a conductor that are part of the overall gate structure. The work functions of the conductor layers are chosen to provide the proper threshold voltages for both n-channels and p-channels. As device size continues to shrink, the reliability of transistors under normal operation has become increasingly problematic. Issues include bias temperature instability (BTI), wherein the transistor characteristics change as a result of voltages applied to the metal gate. Many of these reliability issues are connected with interface states at the boundary between the interface layer and the underlying semiconductor substrate (e.g., silicon, germanium, or silicon-germanium). The problems arise as a result of dangling Si and/or Ge bonds at the interface. Typically, after cleaning, the surface atoms are passivated by weakly bound hydrogen atoms which are easily displaced or removed, resulting in re-activation of the interface.

One approach to stabilizing the dangling Si or Ge bonds is to attach fluorine atoms to the dangling bonds. Fluorine binds strongly to both silicon and germanium, and once bonded, it is believed that the interface becomes more stable. Reliability improvements such as improved bias temperature instability can be attributed to the stronger Si—F and/or Ge—F bond compared to the Si—H and/or Ge—H bond.

However, introducing fluorine to the interface is challenging. Typically, exposure to fluorine-containing gases provides a means of introducing fluorine atoms to the interface, but the control over the amount of delivered fluorine is imprecise. Excess fluorination of the interface has the effect of creating additional dielectric layers that increase the effective dielectric thickness. It is also possible to use ion implantation methods, but these methods tend to damage other materials in the transistor such as the gate dielectric, and they are not suitable for use with three-dimensional structures, because they are highly directional and cannot provide uniform implantation of fluorine atoms.

Methods for incorporating fluorine dopants into the dielectric material during deposition (e.g. atomic layer deposition (ALD)) are described in co-owned and co-pending U.S. patent application Ser. No. 13/480,331, filed on May 24, 2012, which is herein incorporated by reference for all purposes. Methods for incorporating fluorine dopants into the dielectric material by using fluorine doped tungsten silicide as a source of fluorine are described in co-owned and co-pending U.S. patent application Ser. No. 13/728,957, filed on Dec. 27, 2012, which is herein incorporated by reference for all purposes.

In some embodiments, the present invention discloses methods, and structures fabricated from the methods, to incorporate a fluorine and/or nitrogen dopant into a gate dielectric layer. The gate dielectric layer may include at least one of hafnium oxide, hafnium silicon oxide, hafnium aluminum oxide, zirconium oxide, zirconium silicon oxide, zirconium aluminum oxide, titanium oxide, titanium silicon oxide, or titanium aluminum oxide. In the following description, hafnium oxide is used to as an illustrative example, but other high-k dielectrics can be used as indicated.

In some embodiments, the described gate dielectric layer can include a fluorine and/or nitrogen doped material with low defect density and with improved interface trap charge density. For example, fluorine dopants in the doped high-k dielectric layer can passivate the interface states by forming Si—F and/or Ge—F bonds at the interface of the high-k gate dielectric layer and the substrate. Further, fluorine and/or nitrogen dopants in the doped high-k dielectric layer can passivate the bulk traps by forming Hf—F, Zr—F, or TiF bonds in the oxygen vacancies of the high-k gate dielectric layer. The fluorine and/or nitrogen doping process of the high-k gate dielectric layer can thus improve the gate dielectric reliability.

Advances in semiconductor processing have demanded ever-increasing functional density with continuous size scaling. This scaling process has led to the adoption high-k gate dielectrics and metal gate electrodes in metal gate stacks in semiconductor devices.

High-k gate dielectrics can offer a method to reduce the thickness of the gate dielectric while maintaining acceptable gate leakage current. The use of high-k gate dielectrics is often accompanied by a metal gate electrode, since thin gate dielectric layers may cause depletion in polysilicon electrodes, affecting the device operation and performance. Metal gate electrodes further have an advantage of higher electrical conductance, as compared to polysilicon conductors, and thus can improve signal propagation times.

The manufacture of high-k dielectric layers entails the integration and sequencing of many unit processing steps, with potential new process developments, since in general, high-k gate dielectrics are more sensitive to process conditions than silicon dioxide. For example, interface traps and interface oxide formation can adversely affect the performance of the high-k dielectric gate structures.

The microelectronic industry continues to search for new dielectric materials that exhibit high k values (i.e. dielectric constant) and low leakage, to enable further miniaturization of electronic devices. These materials may be used as the dielectric layer in electronic components such as gate dielectric layers, capacitors, memory cell structures, and other devices. The k value is a measure of the polarization capability of dielectric materials in response to external electrical field, which can be used to store charge in capacitors. The ability of a dielectric material to store charge is also conveniently represented by the equivalent oxide thickness (“EOT”). A low EOT implies an increased ability to miniaturize semiconductor devices. The leakage current is a measure of the material's capability to retain stored charge for a period of time. Both EOT and leakage current are important parameters for the miniaturization of electronic components such as gate dielectric layers, capacitors, memory cell structures, and other devices. Typical high-k materials include Al₂O₃ (k˜9), HfSiO (k˜5-20), ZrO₂ (k˜25), HfO₂ (k˜25), Ta₂O₅ (k˜26), and TiO₂ (k˜80).

In some embodiments, high-k gate dielectric layers can replace silicon dioxide gate dielectric layers and provide the lower EOT values required for lower transistor operating voltages and smaller transistor dimensions. The gate dielectric layer may include at least one of hafnium oxide, hafnium silicon oxide, hafnium aluminum oxide, zirconium oxide, zirconium silicon oxide, zirconium aluminum oxide, titanium oxide, titanium silicon oxide, or titanium aluminum oxide.

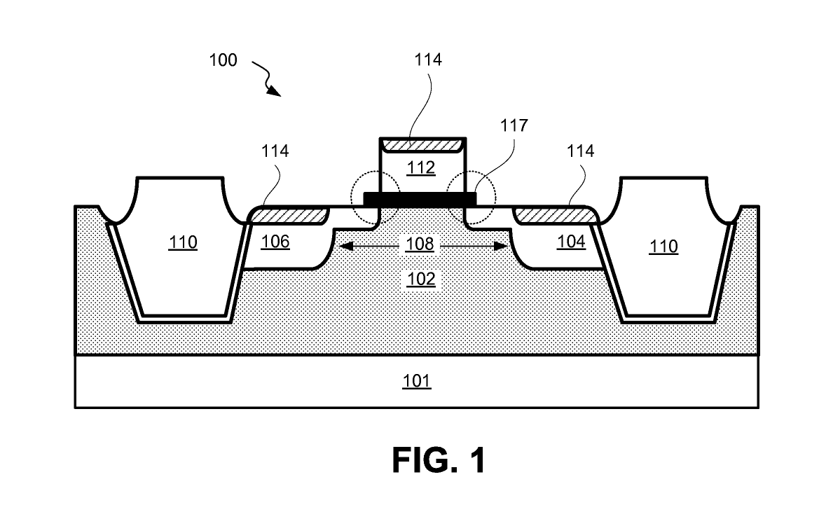

A brief description of semiconductor device examples is presented below to provide better understanding of various plasma surface treatments. Specifically, FIG. 1 illustrates a schematic representation of substrate portions including MOS device, 100, in accordance with some embodiments. The references below are made to positive metal-oxide semiconductor (PMOS) devices but other types of MOS devices can be used in the described processes and will be understood by one having ordinary skill in the art. MOS device, 100, includes a p-doped substrate, 101, and an n-doped well, 102, disposed within substrate, 101. Substrate, 101, is typically a part of an overall wafer that may include other devices. Some of these devices may include silicon nitride, silicon oxide, polysilicon, or titanium nitride structures. P-doped substrate, 101, may include any suitable p-type dopants, such as boron and indium, and may be formed by any suitable technique. N-doped well, 102, may include any suitable n-type dopants, such as phosphorus and arsenic, and may be formed by any suitable technique. For example, n-doped well, 102, may be formed by doping substrate, 101, by ion implantation, for example.

MOS device, 100, also includes a conductive gate electrode, 112, that is separated from n-doped well, 102, by gate dielectric, 117. Gate electrode, 112, may include any suitable conductive material (e.g., titanium nitride, tantalum nitride, hafnium nitride, ruthenium nitride, tungsten nitride, tungsten, molybdenum, tantalum silicon nitride, ruthenium silicon nitride, tungsten silicon nitride, hafnium silicon nitride, titanium silicon nitride, etc). Gate dielectric, 117, is formed from a high-k material (e.g. hafnium oxide). Other dielectric materials include hafnium silicon oxide, hafnium aluminum oxide, zirconium oxide, zirconium silicon oxide, zirconium aluminum oxide, titanium oxide, titanium silicon oxide, or titanium aluminum oxide. Typically, a semiconductor material with high mobility such as germanium or a silicon-germanium alloy (not shown) is formed beneath the gate dielectric.

MOS device, 100, also includes p-doped source region, 104, and drain region, 106, (or simply the source and drain) disposed in n-doped well, 102. Source, 104, and drain, 106, are located on each side of gate electrode, 112, forming channel, 108, within n-doped well, 102. Source, 104, and drain, 106, may include a p-type dopant, such as boron. Source, 104, and drain, 106, may be formed by ion implantation. After forming source, 104, and drain, 106, MOS device, 100, may be subjected to an annealing and/or thermal activation process.

In some embodiments, source, 104, drain, 106, and gate electrode, 112, are covered with a layer of self-aligned silicide portions, 114, which may be also referred to as salicide portions or simply salicides. For example, a layer of cobalt may be deposited as a blanket layer and then thermally treated to form these silicide portions, 114. Other suitable materials include nickel and other refractory metals, such as tungsten, titanium, platinum, and palladium. After forming the blanket layer from the suitable metal, the layer is subjected to rapid thermal process (RTP) to react the metal with silicon contained within gate electrode, 112, as well as within source, 104, and drain, 106, to form a metal silicide. The RTP process may be performed at 700° C. to 1000° C.

MOS device, 100, may also include shallow trench isolation (STI) structures, 110, disposed on both sides of source, 104, and drain, 106. STI structures, 110, may include liners formed on the side and bottom walls by, for example, thermal oxidation of silicon of n-doped well, 102. The main body of STI structures is formed by filling a trench within n-doped well, 102, with a dielectric material, such as silicon oxide. Silicon oxide may be filled using high density plasma (HDP) deposition process.

As shown in FIG. 1, gate dielectric, 117, may protrude beyond gate electrode, 112. As such, gate dielectric, 117, may need to be partially etched such that it does not extend past electrode, 112, and does not interfere with subsequent formation of liners and spacers on sidewalls of gate electrode, 112.

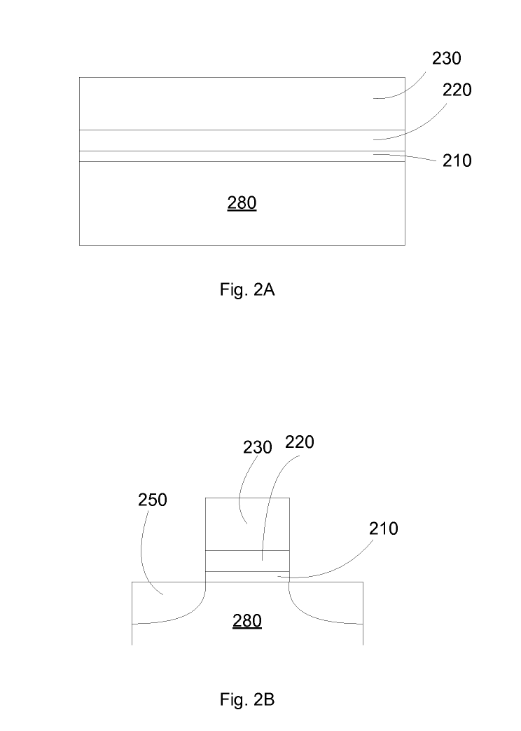

FIGS. 2A-2B illustrates a fabrication sequence for an exemplary gate according to some embodiments. In FIG. 2A, layers of gate dielectric layer, 210, metal gate layer, 220, and gate conductor layer, 230, are deposited on a substrate, 280. The substrate, 280, can be previously processed, for example, to form device well and isolation regions. The structure shown is illustrative, and other configurations can be used, such as a single metal gate layer instead of a metal gate layer, 220, and a gate conductor layer, 230, and a gate dielectric layer stack comprising a high-k dielectric layer on a silicon dioxide pedestal layer instead of a single gate dielectric layer, 210.

The gate dielectric layer, 210, can be formed of a layer of hafnium oxide (or other high-k dielectric material as discussed previously). In some embodiments, the thickness of the gate dielectric layer is less than 10 nm, for example, less than 3 nm. The gate dielectric layer, 210, can be formed by deposition, such as an ALD process.

Disposed on the gate dielectric layer, 210, is a metal gate layer, 220, together with a gate conductor layer, 230. Alternatively, the gate conductor layer, 230, can be omitted, leaving only a metal gate layer, 220. The metal gate layer, 220, typically includes a first metal, and the gate conductor, 230, can either include a polysilicon or a second metal, different from the first metal. In some embodiments, the metal gate layer, 220, is a metal-containing layer, having a metal component together with other combination of materials.

The metal gate layer, 220, can include a refractory metal or a nitride of a refractory metal, such as titanium nitride. Alternatively, the metal gate layer, 220, can include other conductive materials (e.g., titanium nitride, tantalum nitride, hafnium nitride, ruthenium nitride, tungsten nitride, tungsten, molybdenum, tantalum silicon nitride, ruthenium silicon nitride, tungsten silicon nitride, hafnium silicon nitride, titanium silicon nitride, etc). The thickness of the metal gate layer, 220, can be less than 20 nm with the gate conductor layer, or can be less than 200 nm without a gate conductor layer. In some embodiments, the metal gate layer, 220, can include a dopant such as fluorine and/or nitrogen. The dopant may be added to the metal gate layer during the deposition step. The doped metal gate layer may serve as a source of dopants for the high-k dielectric layer during a subsequent anneal step.

The gate conductor layer, 230, can include silicon, such as doped polysilicon. In some embodiments, the gate conductor layer, 230, can include a dopant such as fluorine and/or nitrogen. The dopant may be added to the gate conductor layer during the deposition step. The doped metal gate layer may serve as a source of dopants for the high-k dielectric layer during a subsequent anneal step. Alternatively, the gate conductor layer, 230, can include a second metal, different from the first metal in the metal gate layer, 220. In addition, the gate conductor can be omitted. The thickness of the gate conductor can be less than 200 nm.

The metal gate layer, 220, and gate conductor layer, 230, can be formed by any methods, such as atomic layer deposition (ALD), physical vapor deposition (PVD), chemical vapor deposition (CVD) or plasma enhanced chemical vapor deposition (PECVD).

FIG. 2B shows a device having the gate conductor layer, 230, the metal gate, 220, and the gate dielectric, 210. Any patterning process can be used, for example, lithography patterning process using photoresist mask and dry or wet etching. The layers can be patterned using a plasma etch process or a wet etch process.

After the completion of the metal gate electrode, the substrate can be further processed to form active devices and circuits. For example, additional steps of implanting dopants to form source and drain structures, 250, forming gate spacers, and shallow junctions. Interconnect metal lines can be included, connecting a plurality of active devices to form an integrated circuit. There can be silicide regions (not shown) on the gate conductor layer, 230, for improving contact resistance. The device shown is an exemplary planar device configuration, and other device configurations are also within the scope of the present invention, such as tri-gate transistor configurations, fin-FET configurations, or different types of transistors or devices.

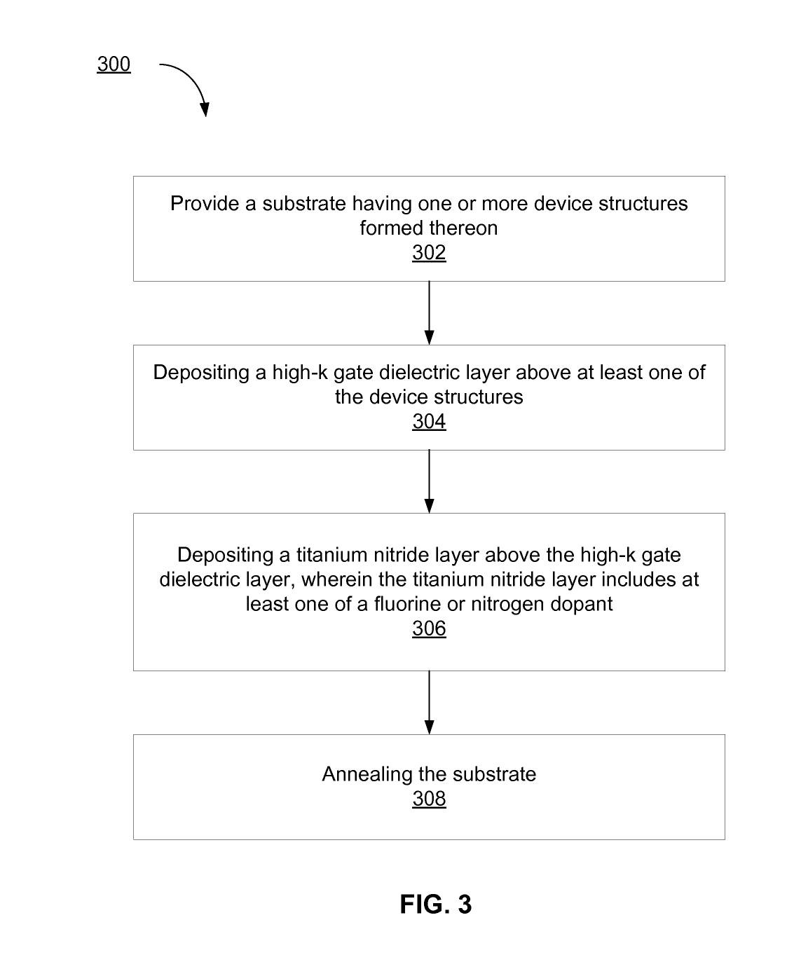

FIG. 3 illustrates a flow chart of an ALD deposition of high-k metal oxide dielectric materials according to some embodiments. In step 302, a substrate is provided having one or more device structures formed thereon.

In step 304, a high-k dielectric layer is deposited above at least one of the device structures. The high-k dielectric layer may include at least one of hafnium oxide, hafnium silicon oxide, hafnium aluminum oxide, zirconium oxide, zirconium silicon oxide, zirconium aluminum oxide, titanium oxide, titanium silicon oxide, or titanium aluminum oxide. In some embodiments, the high-k dielectric layer includes hafnium oxide. The high-k dielectric layer can be deposited by any known deposition process, such as an ALD process. In some embodiments, the thickness of the high-k dielectric layer is less than 10 nm, for example, less than 3 nm.

In step 306, a titanium nitride layer is deposited above the high-k dielectric layer. In some embodiments, the titanium nitride layer includes at least one of a fluorine or a nitrogen dopant. In some embodiments, the titanium nitride layer is operable as a metal gate layer of a high-k gate stack as discussed previously. In some embodiments, the titanium nitride layer is operable as a gate conductor layer of a high-k gate stack as discussed previously.

In some embodiments, the titanium nitride layer deposited in step 306 is deposited using an ALD process. Fluorine may be incorporated (e.g. doped) into the titanium nitride layer by using titanium tetrafluoride (TiF₄) as the titanium precursor. Ammonia may be used as the reactant in the ALD process to form titanium nitride.

In some embodiments, the titanium nitride layer deposited in step 306 is deposited using an ALD process. Typical titanium precursors such as titanium tetrachloride or metal organic-based precursors (e.g. alkyl precursors, β-diketonate precursors, alkoxide precursors, or amino precursors) are well known in the art. Fluorine may be incorporated (e.g. doped) into the titanium nitride layer by periodically exposing the surface to a gas phase fluorine source such as xenon difluoride (XeF₂), nitrogen trifluoride (NF₃), fluorine (F₂), or hydrogen fluoride (HF) during the ALD deposition process (e.g. by inserting a fluorine exposure between some cycles of the ALD deposition process). In some embodiments, an energy source such as a plasma or ultra-violet light may be used to facilitate the reaction of the fluorine with the growing titanium nitride surface. The concentration of fluorine doped into the titanium nitride can be controlled by the frequency and/or the duration of the exposure.

In some embodiments, the titanium nitride layer deposited in step 306 is deposited using an ALD process. Typical titanium precursors such as titanium tetrachloride or metal organic-based precursors (e.g. alkyl precursors, β-diketonate precursors, alkoxide precursors, or amino precursors) as are well known in the art. Nitrogen may be incorporated (e.g. doped) into the titanium nitride layer by periodically exposing the surface to a gas phase nitrogen source such as ammonia (NH₃), nitrogen trifluoride (NF₃), or nitrogen (N₂), during the ALD deposition process (e.g. by inserting a fluorine exposure between some cycles of the ALD deposition process). In some embodiments, an energy source such as a plasma or ultra-violet light may be used to facilitate the reaction of the nitrogen with the growing titanium nitride surface. The concentration of nitrogen doped into the titanium nitride can be controlled by the frequency and/or the duration of the exposure.

In step 308, the substrate is annealed. The annealing step may involve a furnace anneal process or a rapid thermal anneal (RTA) process. Typically, the anneal process is at a temperature between 700C and 900C. A typical RTA anneal process might include heating the substrate to 850C for 1 second. During the anneal step, the dopants (e.g. fluorine and/or nitrogen) can diffuse into the underlying high-k dielectric layer and passivate traps and/or dangling bonds as discussed previously.

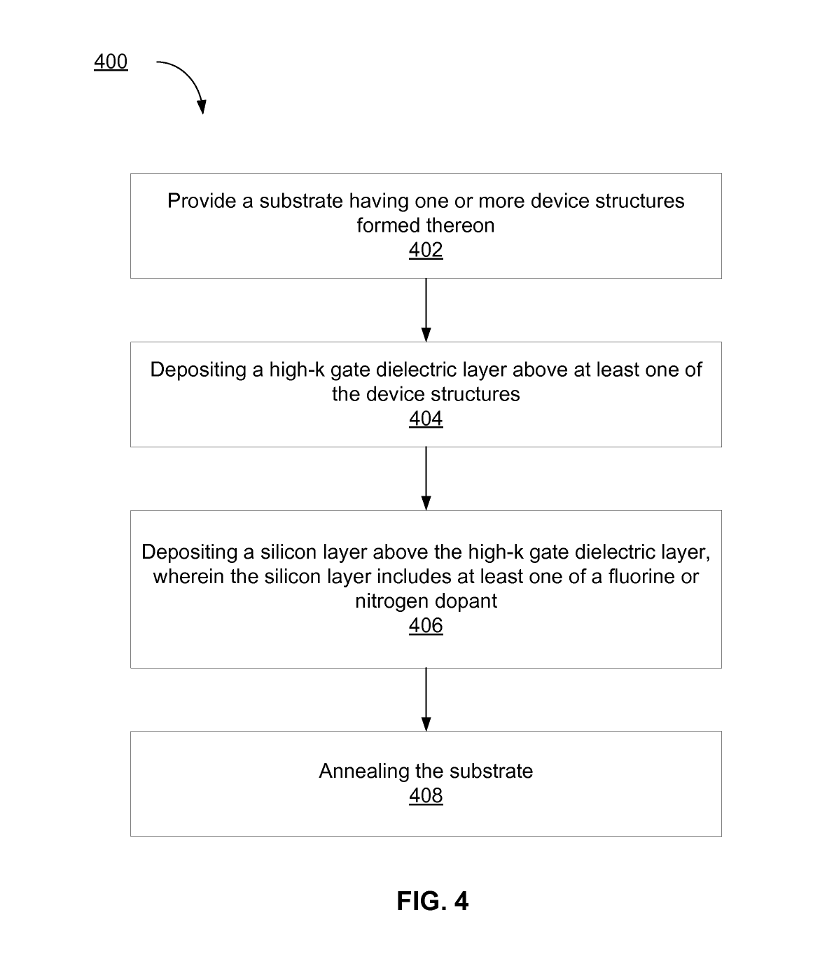

FIG. 4 illustrates a flow chart of an ALD deposition of high-k metal oxide dielectric materials according to some embodiments. In step 402, a substrate is provided having one or more device structures formed thereon.

In step 404, a high-k dielectric layer is deposited above at least one of the device structures. The high-k dielectric layer may include at least one of hafnium oxide, hafnium silicon oxide, hafnium aluminum oxide, zirconium oxide, zirconium silicon oxide, zirconium aluminum oxide, titanium oxide, titanium silicon oxide, or titanium aluminum oxide. In some embodiments, the high-k dielectric layer includes hafnium oxide. The high-k dielectric layer can be deposited by any known deposition process, such as an ALD process. In some embodiments, the thickness of the high-k dielectric layer is less than 10 nm, for example, less than 3 nm.

In step 406, an amorphous silicon layer is deposited above the high-k dielectric layer. In some embodiments, the amorphous silicon layer includes at least one of a fluorine or nitrogen dopant. In some embodiments, the amorphous silicon layer is operable as a cap layer of a high-k gate stack as discussed previously.

In some embodiments, the amorphous silicon layer deposited in step 406 is deposited using one of an ALD, CVD, PECVD, or PVD process. Fluorine may be incorporated (e.g. doped) into the amorphous silicon layer by using tetraethoxysilane (TEOS) as the silicon precursor and hexafluoroethane (C₂F₆) as a fluorine source (e.g. using a PECVD deposition process).

In some embodiments, the amorphous silicon layer deposited in step 406 is deposited using an ALD process. Typical silicon precursors such as metal organic-based precursors (e.g. alkyl precursors, β-diketonate precursors, alkoxide precursors, or amino precursors) are well known in the art. Fluorine may be incorporated (e.g. doped) into the amorphous silicon layer by periodically exposing the surface to a gas phase fluorine source such as xenon difluoride (XeF₂), nitrogen trifluoride (NF₃), fluorine (F₂), or hydrogen fluoride (HF) during the ALD deposition process (e.g. by inserting a fluorine exposure between some cycles of the ALD deposition process). In some embodiments, an energy source such as a plasma or ultra-violet light may be used to facilitate the reaction of the fluorine with the growing amorphous silicon surface. The concentration of fluorine doped into the amorphous silicon can be controlled by the frequency and/or the duration of the exposure.

In some embodiments, the amorphous silicon layer deposited in step 406 is deposited using an ALD process. Typical silicon precursors such as metal organic-based precursors (e.g. alkyl precursors, β-diketonate precursors, alkoxide precursors, or amino precursors) are well known in the art. Nitrogen may be incorporated (e.g. doped) into the amorphous silicon layer by periodically exposing the surface to a gas phase nitrogen source such as ammonia (NH₃), nitrogen trifluoride (NF₃), or nitrogen (N₂), during the ALD deposition process (e.g. by inserting a fluorine exposure between some cycles of the ALD deposition process). In some embodiments, an energy source such as a plasma or ultra-violet light may be used to facilitate the reaction of the nitrogen with the growing amorphous silicon surface. The concentration of nitrogen doped into the amorphous silicon can be controlled by the frequency and/or the duration of the exposure.

In step 408, the substrate is annealed. The annealing step may involve a furnace anneal process or a rapid thermal anneal (RTA) process. Typically, the anneal process is at a temperature between 700C and 900C. A typical RTA anneal process might include heating the substrate to 850C for 1 second. During the anneal step, the dopants (e.g. fluorine and/or nitrogen) can diffuse into the underlying high-k dielectric layer and passivate traps and/or dangling bonds as discussed previously.

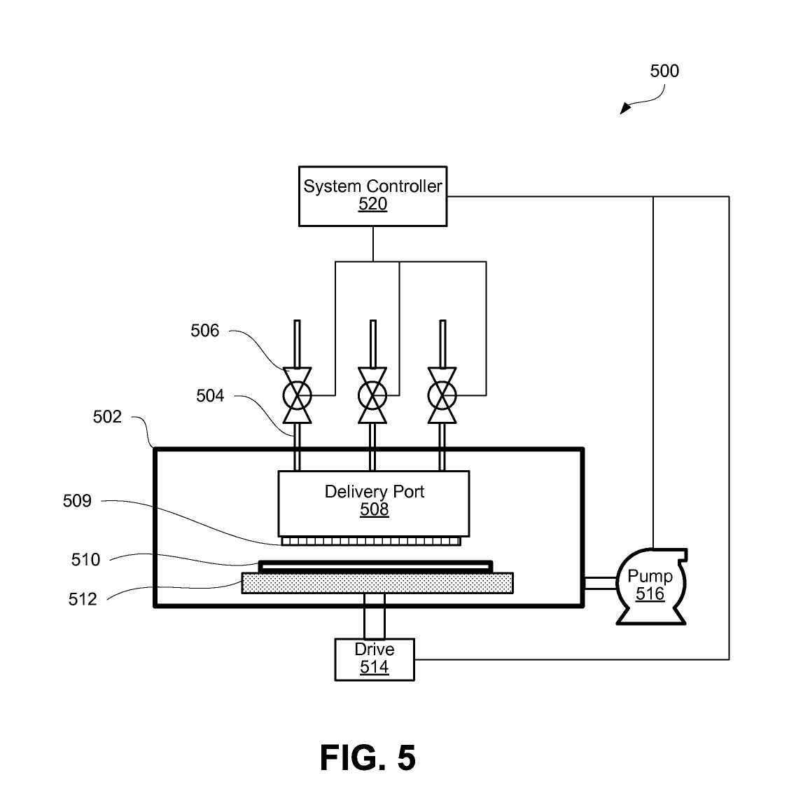

FIG. 5 illustrates a schematic representation of atomic layer deposition apparatus, 500, for fabricating MOS devices, in accordance with some embodiments. For clarity, some components of apparatus, 500, are not included in this figure, such as a wafer-loading port, wafer lift pins, and electrical feedthroughs. Apparatus, 500, includes deposition chamber, 502, connected to processing gas delivery lines, 504. While FIG. 5 illustrates three delivery lines, 504, any number of delivery lines may be used. Each delivery line, 504, may be equipped with a valve and/or mass flow controller, 506, for controlling the delivery rates of processing gases into deposition chamber, 502. In some embodiments, gases are provided into delivery port, 508, prior to exposing substrate, 510, to processing gases. Delivery port, 508, may be used for premixing gases (e.g., precursors and diluents) and even distribution of gases over the surface of substrate, 510. Delivery port, 508, is sometimes referred to as a showerhead. Delivery port, 508, may include a diffusion plate, 509, having multiple holes for gas distribution.

Deposition chamber, 502, encloses substrate support, 512, for holding substrate, 510, during its processing. Substrate support, 512, may be made from a thermally conducting metal (e.g., tungsten, molybdenum, aluminum, nickel) or other like materials (e.g., a conductive ceramic) and may be used to maintain the substrate temperature at desired levels. Substrate support, 512, may be connected to drive, 514, for moving substrate, 510, during loading, unloading, process set up, and sometimes even during processing. Deposition chamber, 502, may be connected to vacuum pump, 516, for evacuating reaction products and unreacted gases from deposition chamber, 502, and for maintaining the desirable pressure inside chamber, 502.

Apparatus, 500, may include system controller, 520, for controlling process conditions during electrode and resistive switching layer deposition and other processes. Controller, 520, may include one or more memory devices and one or more processors with a central processing unit (CPU) or computer, analog and/or digital input/output connections, stepper motor controller boards, and the like. In some embodiments, controller, 520, executes system control software including sets of instructions for controlling timing, gas flows, chamber pressure, chamber temperature, substrate temperature, radio frequency (RF) power levels (if RF components are used, e.g., for process gas dissociation), and other parameters. Other computer programs and instruction stored on memory devices associated with controller may be employed in some embodiments.

Although the foregoing examples have been described in some detail for purposes of clarity of understanding, the invention is not limited to the details provided. There are many alternative ways of implementing the invention. The disclosed examples are illustrative and not restrictive.

1. A method for doping a high-k dielectric layer, the method comprising:
providing a substrate;
depositing a high-k dielectric layer directly above the substrate;
after depositing the high-k dielectric layer, depositing a metal gate layer above the high-k dielectric layer,
wherein the metal gate layer comprises a fluorine doped material comprising at least one of hafnium nitride, ruthenium nitride, ruthenium silicon nitride, or hafnium silicon nitride,
wherein the metal gate layer is deposited using atomic layer deposition, and
annealing the substrate.

2. The method of claim 1 wherein the high-k dielectric layer comprises at least one of hafnium oxide, hafnium silicon oxide, hafnium aluminum oxide, zirconium oxide, zirconium silicon oxide, zirconium aluminum oxide, titanium oxide, titanium silicon oxide, or titanium aluminum oxide.

3. The method of claim 2 wherein the high-k dielectric layer comprises hafnium oxide.

4. The method of claim 1 wherein the fluorine in the fluorine doped material operates to passivate and stabilize dangling Si or Ge bonds at an interface between the substrate and the high-k dielectric layer by forming bonds in the oxygen vacancies of the high-k gate dielectric layer.

5. (canceled)

6. The method of claim 1 wherein a precursor used to deposit the metal gate layer using atomic layer deposition comprises one of a metal organic-based precursor, an alkyl precursor, a β-diketonate precursor, an alkoxide precursor, or an amino precursor.

7. The method of claim 1 wherein a reactant used to deposit the metal gate layer using atomic layer deposition comprises ammonia.

8. The method of claim 1 further comprising doping the metal gate layer material by exposing a surface of the substrate to a gas phase fluorine source during the depositing of the metal gate layer.

9. The method of claim 8 wherein the gas phase fluorine source comprises at least one of xenon difluoride (XeF₂), nitrogen trifluoride (NF₃), fluorine (F₂), or hydrogen fluoride (HF).

10. The method of claim 9 further comprising applying an energy source during the exposing, wherein the energy source is one of a plasma or ultra-violet light.

11. The method of claim 1 further comprising exposing a surface of the substrate to a gas phase nitrogen source after the exposing the surface to the gas phase fluorine source during the depositing of the metal gate layer.

12. The method of claim 11 wherein the gas phase nitrogen source comprises at least one of ammonia (NH₃), nitrogen trifluoride (NF₃), or nitrogen (N₂).

13. The method of claim 12 further comprising applying an energy source during the exposing, wherein the energy source is one of a plasma or ultra-violet light.

14-20. (canceled)

21. The method of claim 1 wherein the fluorine diffuses into the high-k dielectric layer during the annealing.

22. The method of claim 21 wherein the annealing is one of a furnace anneal process or a rapid thermal anneal (RTA) process.

23. The method of claim 22 wherein the annealing is at between about 700° C. and 900° C.

24. The method of claim 22 wherein the annealing is a RTA process wherein the substrate is heated to about 850° C. for about 1 second.

25. The method of claim 1 wherein the high-k dielectric layer has a thickness less than about 3 nm.

26. The method of claim 1 wherein the metal gate layer has a thickness less than about 20 nm.

27. The method of claim 9 wherein a concentration of fluorine doped into the metal gate layer is controlled by one of a frequency or a duration of exposure to the gas phase fluorine source.

28. The method of claim 12 wherein a concentration of nitrogen doped into the metal gate layer is controlled by one of a frequency or a duration of exposure to the gas phase nitrogen source.
